(19) United States
(12) Patent Application Publication
(10) Pub. No.: US 2020/0195763 A1
(43) Pub. Date: Jun. 18, 2020

(54) SECURE PHONE LOCKING AND CHARGING DEVICE

(71) Applicant: Riveted Labs USA, Inc., Brooklyn, NY (US)

(72) Inventor: Theodore Ellis, Seattle, WA (US)

(21) Appl. No.: 16/676,966

(22) Filed: Nov. 7, 2019

Related U.S. Application Data
(60) Provisional application No. 62/780,008, filed on Dec. 14, 2018.

(51) Int. Cl. H04M 1/02; H05K 5/02; H05K 5/00; G06F 1/16; G08B 3/10; F21V 33/00

(52) U.S. Cl. CPC H04M 1/026; H05K 5/0221; F21V 33/0004; G06F 1/1632; G08B 3/10; H05K 5/0086

(57) ABSTRACT

Systems, devices and methods for securely locking and charging a mobile device, for example, a smartphone, providing a physical separation between a user and the device.

### CROSS REFERENCE TO RELATED APPLICATIONS

The present application claims priority pursuant to U.S.C. § 119(e) to U.S. Provisional Patent Application No. 62/780,008 filed Dec. 14, 2018, the entire content and disclosure of which is hereby incorporated by reference in its entirety.

The present application is related to U.S. patent application Ser. No. 16/538,256 filed Aug. 12, 2019, the entire content and disclosure of which is hereby incorporated by reference in its entirety.

### FIELD

The subject matter described herein relates generally to a phone locking device. More particularly, it relates to a secure phone locking device that may also charge the phone.

### BACKGROUND

Statistics have shown that most users are hooked on smartphones. The average smartphone user glances at her phone 80 times a day (30,000 times a year). The most recent studies show average mobile device usage of 4 to 5 hours per day, but this figure is increasing at a double-digit percentage year-over-year. Yet 40% of the time users unlock their smartphones they are not consciously aware of the reason they are doing so. Teenagers are perhaps the most hooked on their smartphones: 50% describe themselves as addicted and 78% check their devices at least hourly. But adults are just as hooked. Most American adults will readily share anecdotal evidence of shortening attention spans and diminished workplace productivity. Studies have shown a decline in cognitive abilities equivalent to 10 IQ points when a phone is simply physically present and accessible. In fact, in controlled studies, even increasing proximity to the accessible phone (in a pocket vs. on a table vs. in another room) leads to reduced performance on tests of cognitive abilities.

A need therefore exists to develop systems, devices and methods for securely storing and locking a smartphone that overcome these and other limitations of the prior art. These systems, devices and methods may also charge the stored smartphone, and unlock using an entertaining challenge.

### SUMMARY

Provided herein are embodiments of system and methods for securely locking and charging a mobile device, for example, a smartphone, providing a physical separation between a user and the device. The system and methods may not fully restrict access to the phone but may provide a meaningful obstacle to obsessive use. In various embodiments, the present disclosure may generally provide a system comprises a phone charging dock that may lock a user's phone inside an enclosure. In order to unlock the enclosure, and retrieve the phone, the user may need to solve a puzzle (or challenge) using, for example, colored buttons positioned on the top of the enclosure. In some embodiments, the puzzle may be a random series of illuminated colored buttons that the user needs to repeat in the correct sequence. Once the user unlocks and opens the enclosure, the user can remove the phone. In some embodiments, once the phone is removed from the charging dock, the system may sound an alarm after a predetermined amount of time, for example, 60 seconds, if the phone has not been returned to the charging dock. In some embodiments, in subsequent times the user wants to remove the phone from the system, the difficulty of the puzzle may increase progressively.

In some embodiments, the system and methods described herein provide an automated process for securely locking and charging a smartphone. Applications for the system and methods may include, for example, a way for parents (or teachers, employers) to keep kids (or students, employees) off their phones without taking the phone away entirely. It makes the immediate gratification of reaching for the phone a little less tempting to the child (student, employee), e.g., because she has to solve a puzzle. At the same time, the puzzle can be a game that builds memory. Other uses may include in schools, or in workplace settings where smartphone use is a safety hazard or regulatory risk (e.g., construction sites, hospitals, factories, warehouses).

The foregoing methods may be implemented in any suitable programmable computing apparatus, by provided program instructions in a non-transitory computer-readable medium that, when executed by a computer processor, cause the apparatus to perform the described operations. The processor may be local to the apparatus and user, located remotely, or may include a combination of local and remote processors.

Other systems, apparatus, methods, features and advantages of the subject matter described herein will be or will become apparent to one with skill in the art upon examination of the following figures and detailed description. It is intended that all such additional systems, devices, methods, features and advantages be included within this description, be within the scope of the subject matter described herein, and be protected by the accompanying claims. In no way should the features of the example embodiments be construed as limiting the appended claims, absent express recitation of those features in the claims.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Moreover, it is noted that the invention is not limited to the specific embodiments described in the Detailed Description and/or other sections of this document. Such embodiments are presented herein for illustrative purposes only. Additional embodiments will be apparent to persons skilled in the relevant art(s) based on the teachings contained herein.

### BRIEF DESCRIPTION OF THE FIGURES

The details of the subject matter set forth herein, both as to its structure and operation, may be apparent by study of the accompanying figures, in which like reference numerals refer to like parts. The components in the figures are not necessarily to scale, emphasis instead being placed upon illustrating the principles of the subject matter. Moreover, all illustrations are intended to convey concepts, where relative sizes, shapes and other detailed attributes may be illustrated schematically rather than literally or precisely.

FIG. 1 illustrates an exemplary front perspective view of a secure phone locking and charging device, in accordance with an embodiment of the present disclosure.

FIG. 2 illustrates an exemplary bottom perspective view of a secure phone locking and charging device, in accordance with an embodiment of the present disclosure.

FIG. 3 illustrates an exemplary front perspective exploded view of a secure phone locking and charging device, in accordance with an embodiment of the present disclosure.

FIG. 4 illustrates an exemplary bottom perspective exploded view of a secure phone locking and charging device, in accordance with an embodiment of the present disclosure.

FIG. 5 illustrates an exemplary right side, sectional view of a secure phone locking and charging device, in accordance with an embodiment of the present disclosure.

FIG. 6 illustrates an exemplary front perspective view of a top portion of a secure phone locking and charging device, in accordance with an embodiment of the present disclosure.

FIG. 7 illustrates an exemplary right side, sectional view of a top portion of a secure phone locking and charging device, in accordance with an embodiment of the present disclosure.

FIG. 8 illustrates an exemplary front perspective view of a bottom portion of a secure phone locking and charging device, in accordance with an embodiment of the present disclosure.

FIG. 9 illustrates an exemplary inside view of a bottom portion of a secure phone locking and charging device, in accordance with an embodiment of the present disclosure.

FIG. 10 is a high-level flow diagram illustrating an exemplary process for receiving and processing inputs for a secure phone locking and charging device, in accordance with an embodiment of the present disclosure.

FIG. 11 illustrates an exemplary simplified schematic diagram of a secure phone locking and charging device, in accordance with an embodiment of the present disclosure.

FIGS. 12-21 illustrates exemplary schematic diagrams of some components of a secure phone locking and charging device, in accordance with an embodiment of the present disclosure.

### DETAILED DESCRIPTION

Before the present subject matter is described in detail, it is to be understood that this disclosure is not limited to the particular embodiments described, as such may, of course, vary. It is also to be understood that the terminology used herein is for the purpose of describing particular embodiments only, and is not intended to be limiting, since the scope of the present disclosure will be limited only by the appended claims.

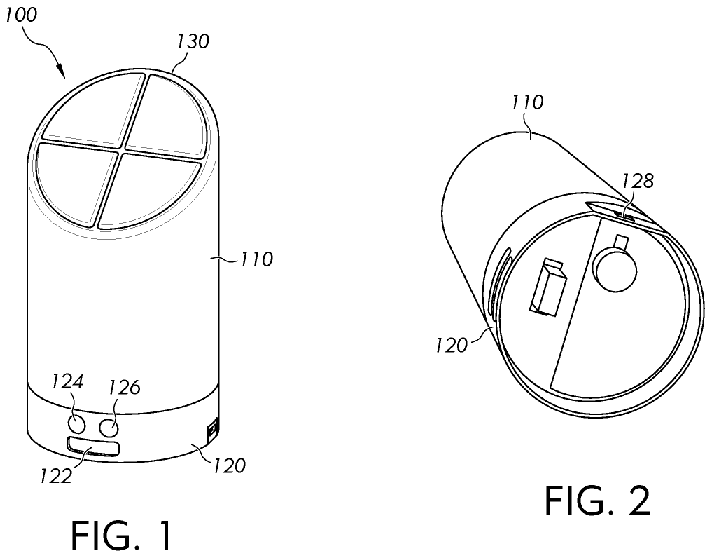

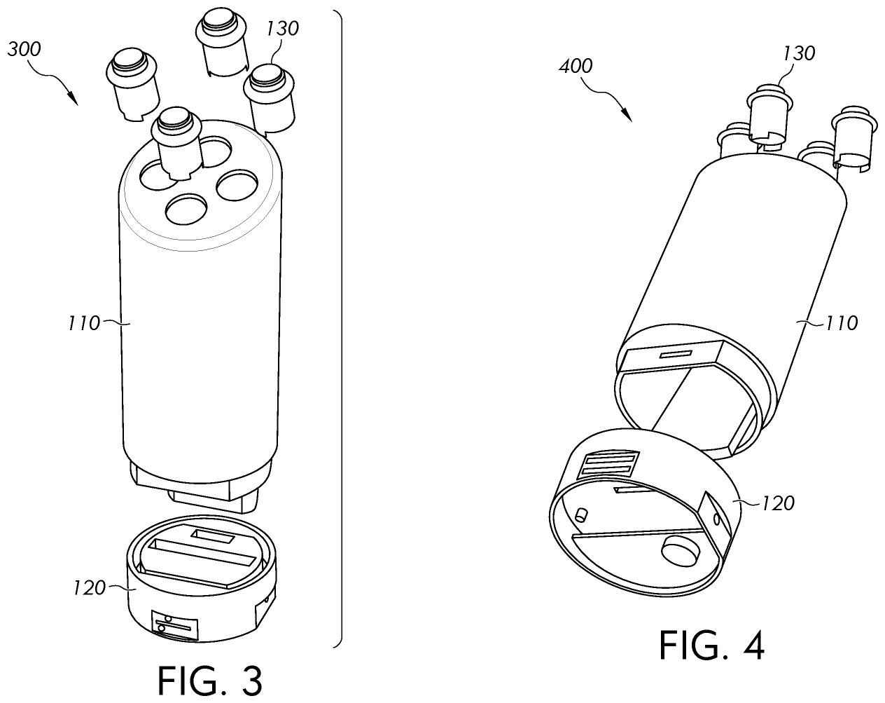

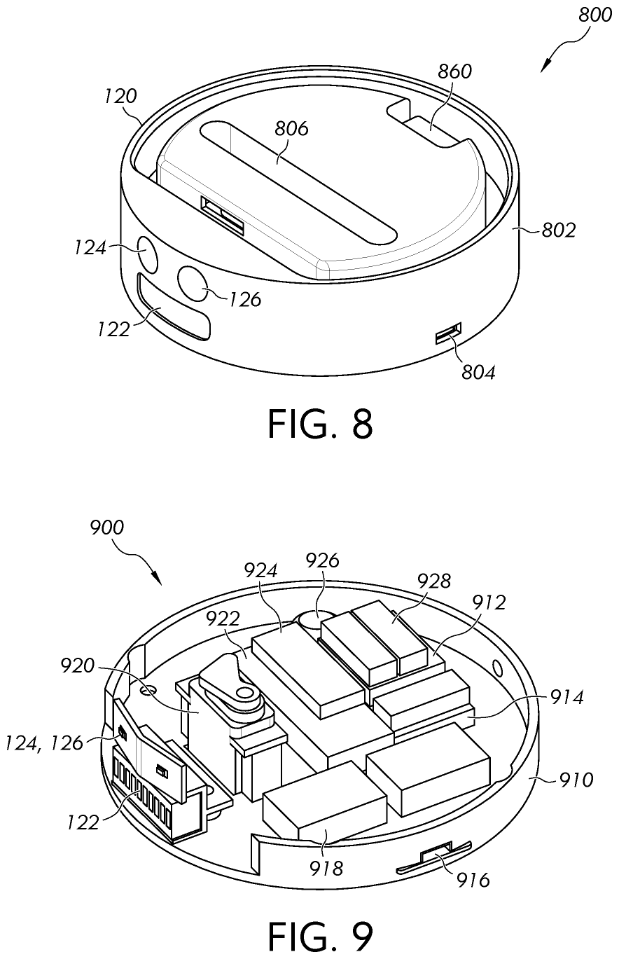

FIG. 1 illustrates an exemplary front perspective view of a secure phone locking and charging device 100, in accordance with some embodiments of the present disclosure. In some embodiments, the secure phone locking and charging device 100 (or simple “device 100”) may generally include a cover 110 and a base 120. The top surface of the cover 110 may include a plurality of color buttons 130. Although illustrated as having four illuminating color buttons, the device 100 may have fewer or more color buttons, and may also have other operating/functional buttons (not shown). In some embodiments, the color buttons 130 may be illuminated with LED lights. Although shown in triangular shape, the color buttons 130 may be in other shape (see, e.g., FIG. 3). The base 120 (described further in FIG. 8) may include various operating/functional buttons and features, for example, status bar 122 and indicators 124, 126.

FIG. 2 illustrates an exemplary bottom perspective view of the secure phone locking and charging device 100, in accordance with some embodiments of the present disclosure. In some embodiments, the base 120 may include a power connector 128 for connecting the device 100 to a power source and/or for charging.

FIGS. 3-4 illustrate exemplary exploded views 300 and 400 of the secure phone locking and charging device 100. Generally, the device comprises a top (or cover) portion 110 and a bottom (or base) portion 120. A user can remove the top cover portion 110 from the bottom base portion 120 to dock a mobile device, e.g., a phone in the base 120 or to remove a phone from the base 120.

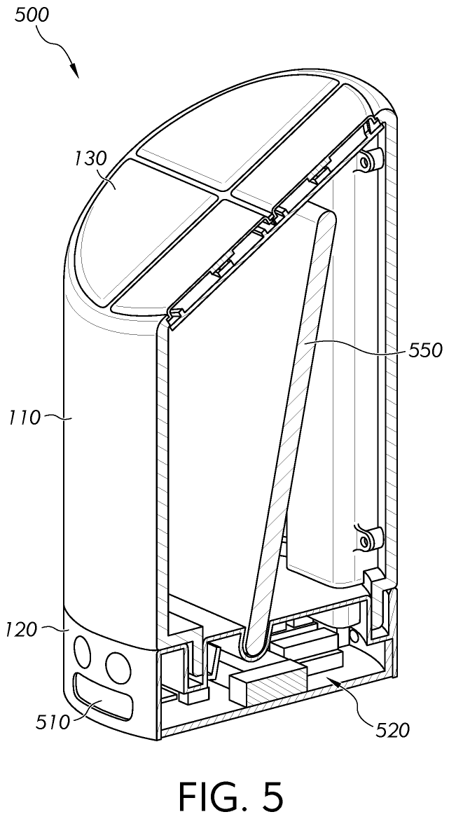

FIG. 5 illustrates an exemplary right side, sectional view 500 of the secure phone locking and charging device 100, in accordance with some embodiments of the present disclosure. The device 100 may include top cover 110 (may also be referred to as dock top) and base 120 (may also be referred to as dock base) as described above. The sectional view 500 illustrates the exemplary internal electronics components 510 positioned in the base 120. The base 120 may also include base user interface (UI) 510, which may include status bar 122 and indicators 124, 126 as shown in FIG. 1. FIG. 5 shows an example of a phone 550 docked inside the device 100. The phone 550 may dock on the base 120, then be covered by the top 110. As will be described further, the phone 550 may then be securely locked when the cover 110 is secured on the base 120.

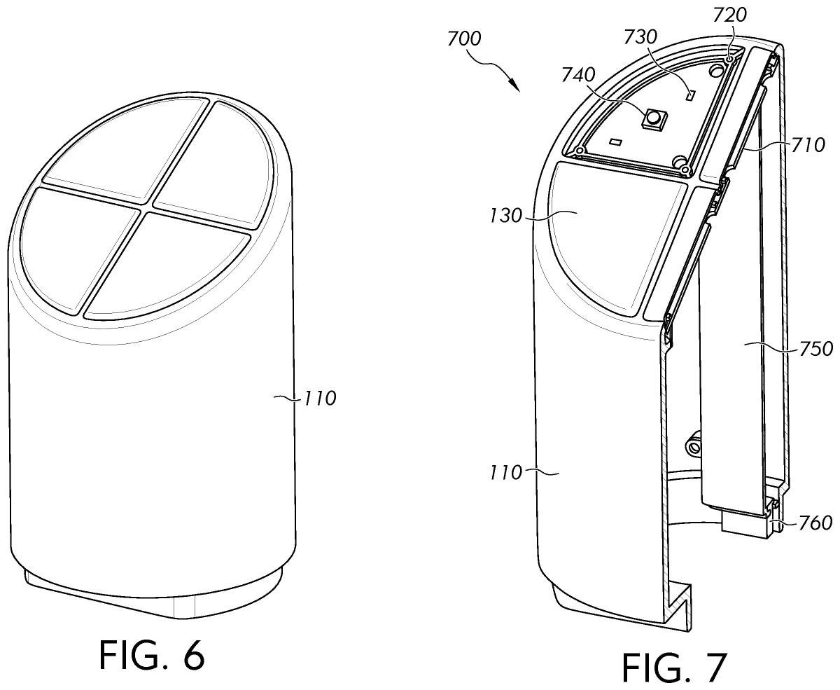

FIG. 6 illustrates an exemplary front perspective view of the top portion 110 of the secure phone locking and charging device 100, while FIG. 7 shows its sectional view 700, in accordance with some embodiments of the present disclosure. As described above, the top portion 110 operates as a cover for the device 100. The cover can be locked and unlocked using the color buttons 130 and will be described further below. The cover 110 may include the top surface 710, which includes the color buttons 130. Each button 130 may include spring 720 and color LED 730. In some embodiments, when a user pushes down on the button 130, contact is made with push connection 740 which may cause communication with electronics components in the base 120. Communication with the base 120 may be facilitated by electronics wiring along the wall of the cover 110 (covered with wire cover 750) and top connector 750, connecting to the base 120.

FIG. 8 illustrates an exemplary front perspective view 800 of a bottom base portion 120 of the secure phone locking and charging device 100, in accordance with some embodiments of the present disclosure. FIG. 9 illustrates an exemplary inside view 900 of a bottom portion 120 of the device 100, showing some internal components, in accordance with some embodiments of the present disclosure. In some embodiments, the base 120 may include base cover 802 and bottom cover 910. Most electronics may be located on the bottom cover 910 and covered by the base cover 802. As shown earlier, the base cover may include interfaces to show status bar 122, charging indicator 124, and active/inactive indicators 126. An override key slot 804 may be provided to access a reset or override function. It should be noted that other interfaces may also be included as the above examples are not meant to be limited.

The cover 802 may include a docking slot 806 for receiving a mobile device. The docking slot 806 may also function as a charging dock.

The base connector 860 may connect with the top connector 760 to provide connections (electrical, signal, etc.) between components located in the top cover 110 and components in the base 120.

In some embodiments, the electronics and other components shown in FIG. 9 may include a built-in USB port 916 and USB splitter connections 918. In some embodiments, the device may include a suitable power converter cable (USB-C or lightning port) for attaching a phone. The base components may include baseboard 922 (e.g., an Arduino Nano board) with a microcontroller unit (MCU) (not shown) that detects when the phone is present and activate an LED on the base to indicate the phone is being charged. Other components may include, for example, battery 924, sound buzzer 936, shift register 928, current sensor 912, charger 914, locking servo 920, and so on. Although LiPo battery is shown, other suitable battery may also be used. In some exemplary operations, a user may place a phone into the docking slot 806, place the top cover portion 110 over the bottom base portion 120 to securely store and charge the phone inside the device 100.

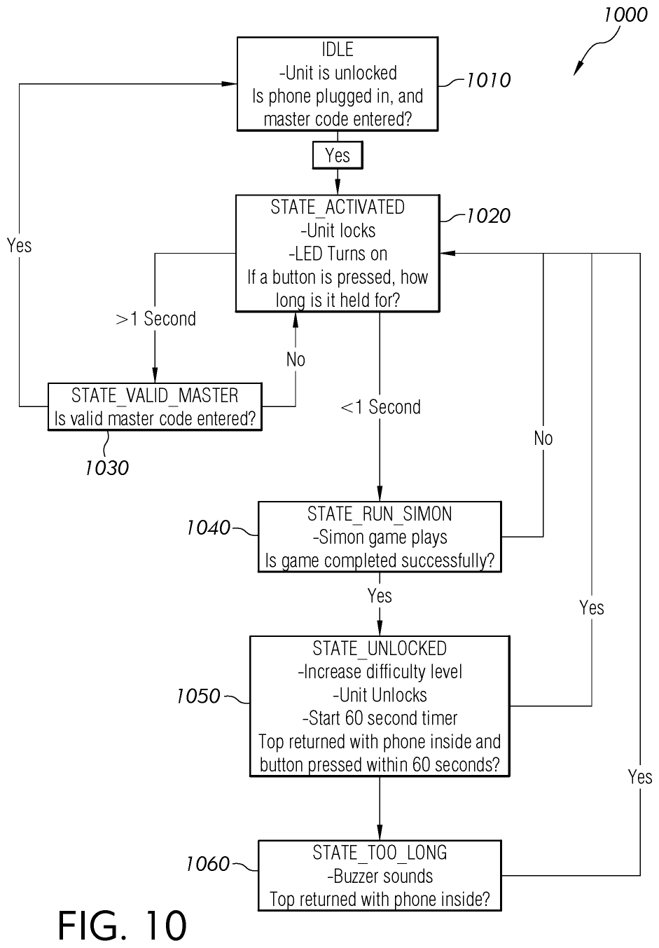

FIG. 10 is a high-level electrical/software flow diagram illustrating an exemplary process 1000 and internal program states of the device 100 for receiving and processing inputs, in accordance with some embodiments of the present disclosure. At 1010 the device 100 is in an IDLE state and is unlocked. In some embodiments, when an operator, for example a parent or teacher or manager, places a phone in the docking slot, places the cover 110 on the base 120, the operator may enter an “admin code”, e.g., a sequence of at least one color button 130 to lock the cover 110, thus activates the device 100. In other embodiments, a designated button (one of the buttons 130, or an additional button—not shown) may be provided to lock the device. Once the device is locked, an LED indicator (e.g., indicator 126) may light up. The device may be in an ACTIVATED or ACTIVE state 1020. In some embodiments, the operator may hold any button (or a predetermined button) for a predetermined time, for example 1-5 seconds, and then reenters the admin code at state 1030. This may be used, for example, to unlock the device, which returns to IDLE state 1010.

Not shown in FIG. 10 is UNPLUGGED state. When the device is active, and the power cord is pulled, a buzzer may sound, the device may go into sleep/idle mode.

In some embodiments, when the device is activated, a servo motor 920 locks the top cover portion 110 of the enclosure to the bottom base 120 via a physical arm.

In order to unlock the device in an ACTIVE state, the user may first press any of the color buttons. In some embodiments, the user may need to press the button for less than the predetermined time to unlock (1-5 seconds) as described above. The device then enters PLAY state 1040, generates a sequence of illumination of the color buttons (a “puzzle”) and waits for input from the user. In some embodiments, the sequence is randomly generated. The user must repeat the same sequence by pressing the color buttons. If the sequence inputted by the user is correct, the device unlocks the cover, enters UNLOCKED state 1050, and an unlock LED indicator lights up. In some embodiments, after the unlock indicator lights up, the user may hold any of the color buttons for a short amount of time, for example, 2 seconds. The device will then transition into the UNLOCKED, or DEACTIVATED, or INACTIVE state 1050. In some embodiments, the system may produce a sound (for example, a short beep) to indicate to the user that the device is unlocked or deactivated for removing the top cover and the phone.

In some embodiments, after removing the phone and placing the cover back on to the bottom base, the user may need to press any of the color buttons to lock the device again, putting the device into LOCKED or ACTIVE state. In some embodiments, if the user does not press a button (e.g., after a predetermined amount of time, e.g. 60 seconds), after placing the cover back on to the bottom base, the device may produce an alarm sound at TOO_LONG state 1060.

Back to state 1040, if the user fails to repeat the sequence of illumination of the color buttons (the “puzzle”), for example by entering a wrong sequence, the device may light a designated LED light to indicate failure. The device stays in (returns to) the locked state 1020. The device will then produce another sequence of colors so that the user can try again. In some embodiments, the level of difficulty of the “puzzle” may stay the same. In some embodiments, the level of difficulty of the “puzzle” may increase progressively over the level of difficulty of a previous sequence. The level of difficulty may increase by playing the sequence faster, or longer (e.g., with more instances of illuminating buttons), or both.

In some embodiments, if the user unplugs the device, a (coin) battery may power a Piezo speaker to sound the alarm.

After the device unlocks, the user may remove the phone from the dock. In some embodiments, the device may light an LED indicator (e.g., at the front of the base) to indicate that an alarm counter is activated. The alarm counter may be activated for a pre-determined amount of time, for example 60 seconds. When the alarm goes off (the alarm counter expires or exceeds the threshold time), the device may produce an alarm sound. The device may also light an alarm LED indicator. At this time, the user needs to dock the phone (plug back in the base) and place the top cover back on the base for the alarm to stop. In some embodiments, the user may need to press a button to indicate she is ready to lock the device.

When the user wants to remove the phone the next times, in some embodiments, the device generates progressively more difficult sequence of colors (“puzzle”). In some embodiments, a ‘difficulty bar’ of LEDs on the device (e.g., bar 122 or another bar) increases by one increment each time the phone is removed from the device.

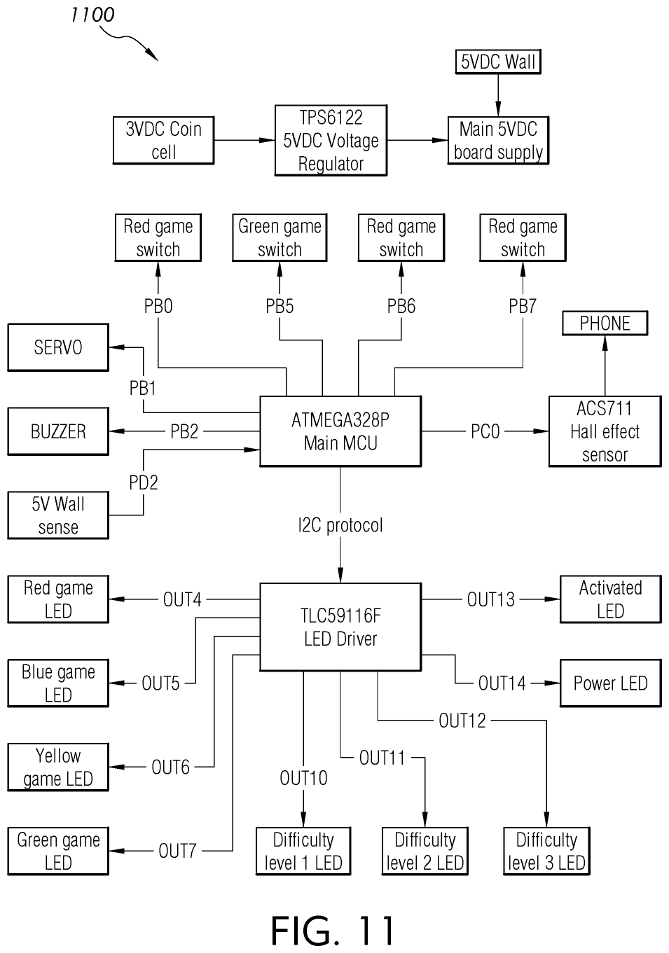

FIG. 11 illustrates an exemplary simplified schematic diagram 1100 of the secure phone locking and charging device 100, in accordance with some embodiments of the present disclosure. Atmega328 is the main MCU that is programmed and everything else is connected to. ACS711 is a hall effect sensor used to detect the amount of current flowing from the main power rail to the phone as it is charging. NC7SZ14 is a Schmitt trigger invertor used to help switch the device from battery power to main power. TLC59116F is an I2C controlled LED driver that controls all the LEDs on the device. TPS6122 is a low power voltage boost convertor which may boost the 3 v from the coin cell to the 5 v needed to power all components. It should be noted the above components are illustrative and other electronics chips and components may be used.

In some embodiments, the pin map of the MCU may be configured as follows:

Switches:
Red—PB0—D8
Green—PD5—D5
Yellow—PD6—D6
Blue—PD7—D7

Game LEDs:
Red—OUT4
Blue—OUT5
Yellow—OUT6
Green—OUT7

Other LEDS:
Difficulty1—OUT10—D3—White
Difficulty2—OUT11—D4—White
Difficulty3—OUT12—D5—White
Power—OUT13—D6—Blue
Active—OUT14—D7—Red

Others:
Servo—PB1—D9
Buzzer—PB2—D10
Current Sense—PC0—A0
5V Wall—PD2—D2

In some embodiments, an electronic board positioned in the base portion of the device may be powered by a 5V USB plug, with a small coin cell battery to provide some functionality when unplugged. When plugged into an electrical outlet, the board may have full functionality of all components (for example, LEDs, Servo, and USB outlet). The USB outlet may operate to charge a phone at up to 3 Amps and may be monitored by a hall effect sensor to detect the current draw, enabling the device to know when a phone is being charged.

In some embodiments, when the electrical 5V outlet connection is disconnected, the board may lose all functionality of components other than the main MCU and a single Piezo buzzer. This is to ensure that the board does not draw more than the maximum 1 c current from the small 100 mAH battery in some embodiments.

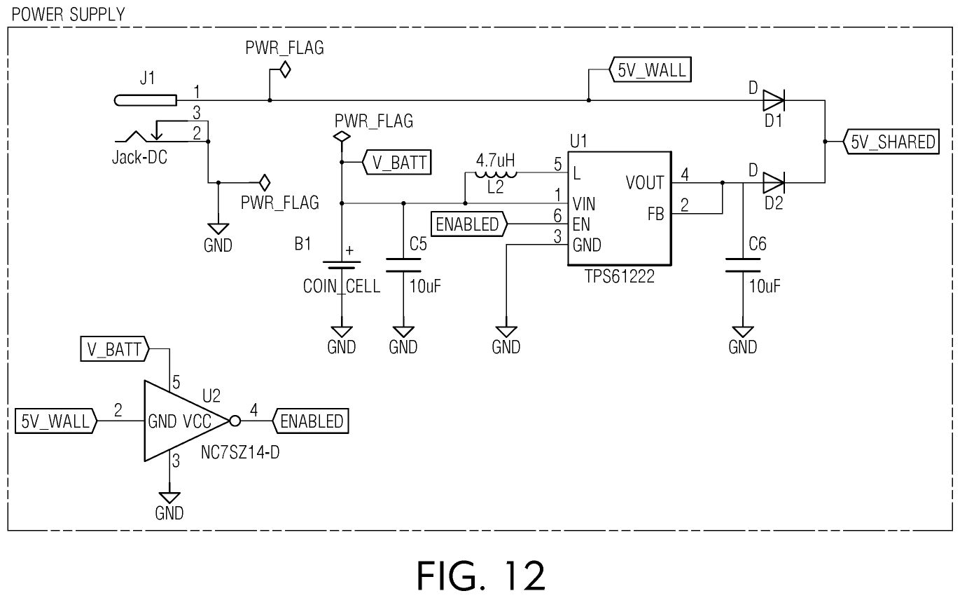

FIGS. 12-21 illustrates exemplary schematic diagrams of some components of the secure phone locking and charging device, in accordance with some embodiments of the present disclosure. In FIG. 12, Power Supply block, the label “5V_WALL” is in between two diodes to prevent any connections that have power given by the wall supply to draw power from the “5V_SHARED.” In some embodiments, only the MCU/CPU (shown as Atmega) has power from the shared power, everything else draws from the wall supply.

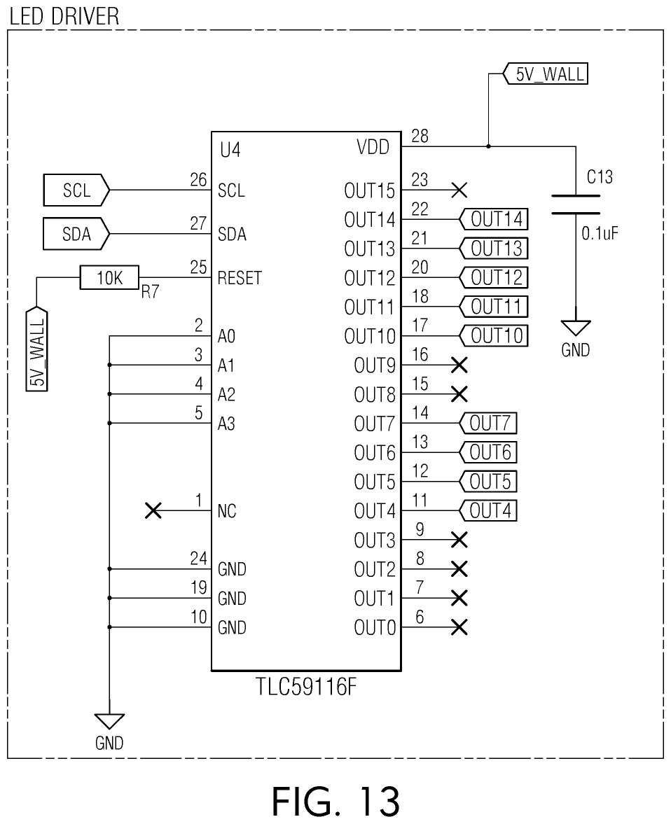

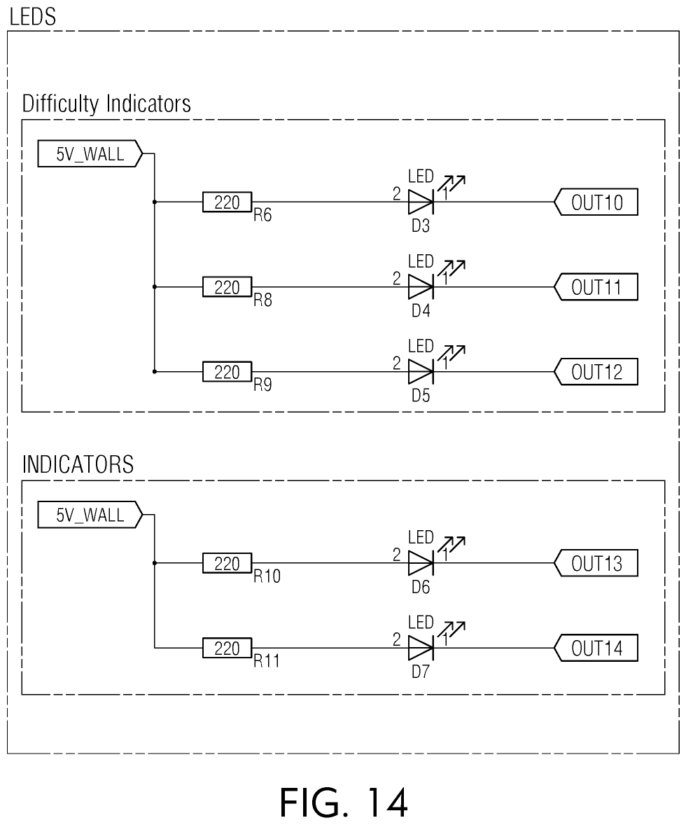

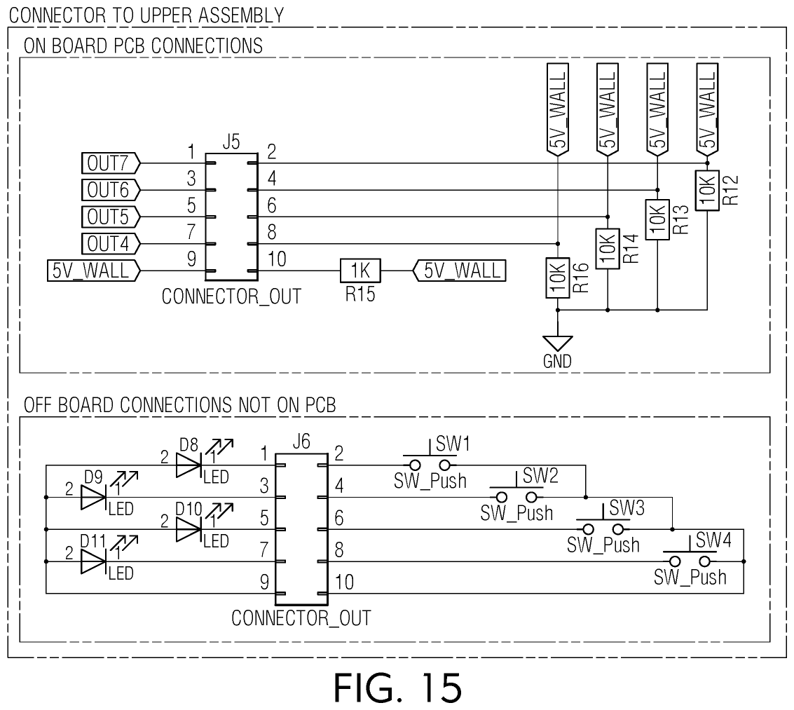

FIG. 13 illustrates an exemplary schematic for a LED driver, in accordance with some embodiments of the present disclosure. FIG. 14 illustrates an exemplary schematic for LEDS and indicators, in accordance with some embodiments of the present disclosure. FIG. 15 illustrates an exemplary schematic for connector to the upper assembly, including on-board PCB connections and off-board connections not on the PCB, in accordance with some embodiments of the present disclosure.

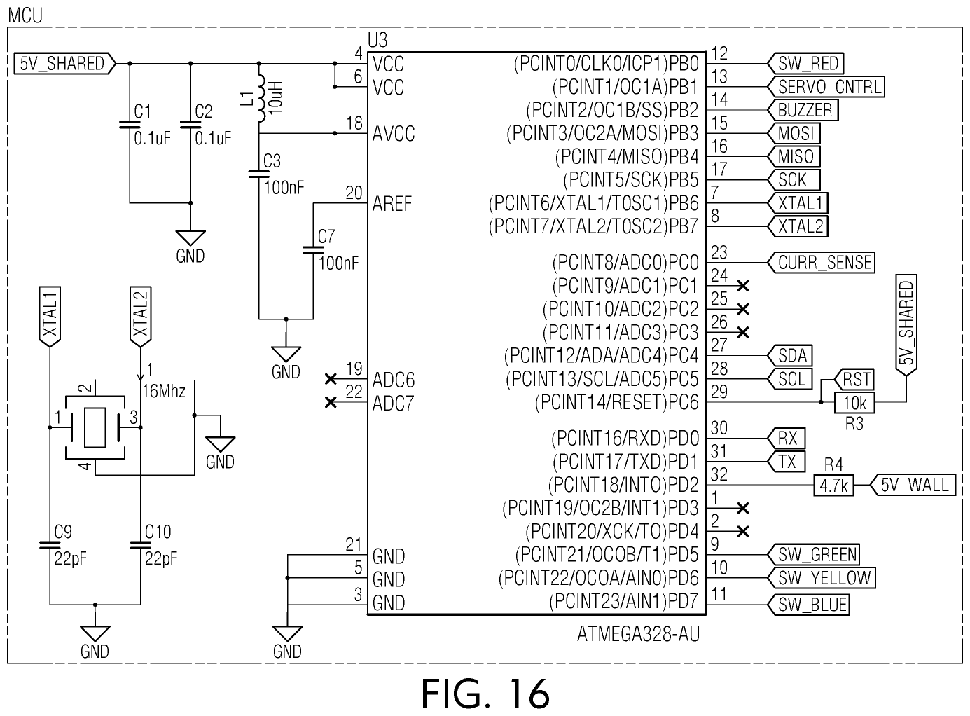

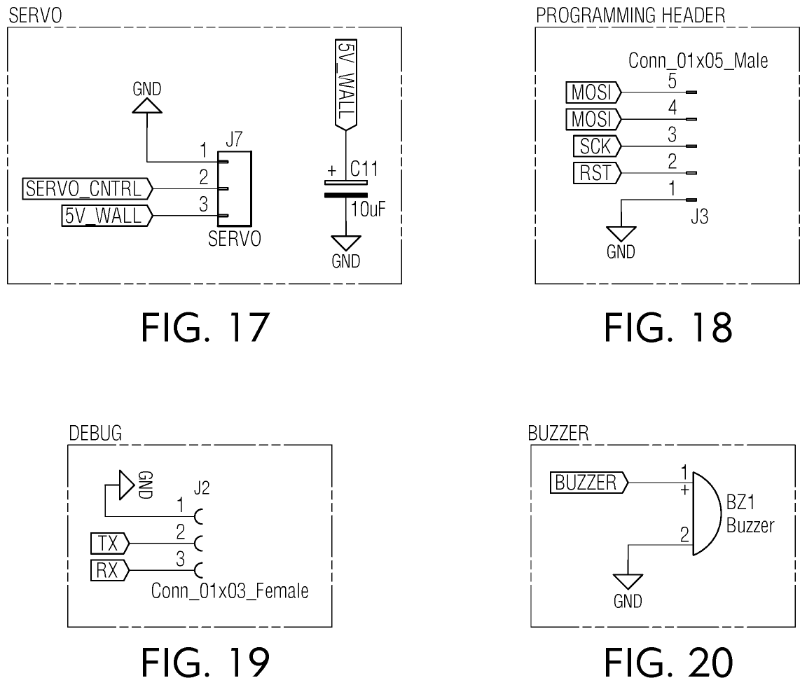

FIG. 16 illustrates an exemplary schematic for a MCU, in accordance with some embodiments of the present disclosure. FIG. 17 illustrates an exemplary schematic for a Servo, in accordance with some embodiments of the present disclosure. FIG. 18 illustrates an exemplary schematic for a programming header, in accordance with some embodiments of the present disclosure. FIG. 19 illustrates an exemplary schematic for debug, in accordance with some embodiments of the present disclosure. FIG. 20 illustrates an exemplary schematic for a buzzer, in accordance with some embodiments of the present disclosure.

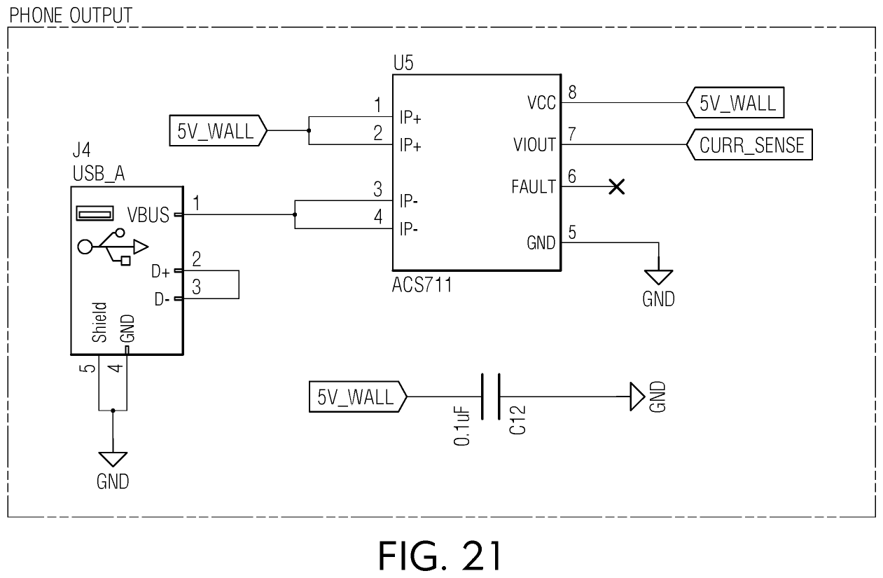

FIG. 21 illustrates an exemplary schematic for a phone output, in accordance with some embodiments of the present disclosure.

In some embodiments, the MCU (FIG. 16) may use a standard ATmega328 in the recommended supply connections. Since ADC may be used for the current sensor, the AVCC may be filtered using a lowpass filer and AREF is decoupled. 16 MHz crystal may be used, and the power may be supplied from the shared 5 v, so this chip may always have power, and may be able to supply power to the buzzer. PD2 may be used to sense when the wall (external) power is removed, and the battery supply is active.

In some embodiments, for the LED, an I2C LED driver may be used, powered from the wall 5 v. The current for each output is controlled by external resistors on the LED blocks. A0-A3 are grounded to give the default i2c address. 4.7 k pullups are used on the i2c lines.

In some embodiments, LEDs may be powered from the driver, 0 hm shunt resistors may be used for the “game” (challenge) resistors because they have internal resistors. 0 hm may be used in case a different LED is used that does not have an internal resistor.

In some embodiments, for the phone output, an ACS711 may be used to detect when the phone is attached to the USB-A output. Bypass cap size may be used.

In some embodiments, for the color buttons, standard switch hardware may be used, but debouncing may be done in software. In some embodiments, standard servo configuration may be used.

Although shown as a cylinder shape, the device may use a different form factor (for example, book shape, handheld shape, or a slimmer vertical shape). The device may be made of different materials, for example, metal, wood, or injection-molded plastic. In some embodiments, the device may also include a physical key and lock.

In some embodiments, a wireless charging mechanism may be used instead of or in addition to the USB port. A wireless (Bluetooth and/or Wi-Fi) component in the device may allow it to connect directly to other Bluetooth enabled devices or to a Wi-Fi network. The wireless component may enable the creation of a mobile app to control the device with greater ease and configurability. As an exemplary application, a wireless device may remotely control the locking of the secure phone locking and charging device of the disclosure and change the puzzle on the device.

In some embodiments, when the secure phone locking and charging device can be controlled and operated by wireless or remote devices, without using the color buttons on the cover, the secure phone locking and charging device may not include the color buttons.

While embodiments of the present invention have been shown and described, various modifications may be made without departing from the spirit and scope of the present invention, and all such modifications and equivalents are intended to be covered.

As used herein and in the appended claims, the singular forms “a”, “an”, and “the” include plural referents unless the context clearly dictates otherwise.

In the following description and in the figures, like elements are identified with like reference numerals. The use of “e.g.,” “etc,” and “or” indicates non-exclusive alternatives without limitation, unless otherwise noted. The use of “including” or “includes” means “including, but not limited to,” or “includes, but not limited to,” unless otherwise noted.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B”, when used in conjunction with open-ended language such as “comprising” can refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

Various aspects have been presented in terms of systems that may include several components, modules, and the like. It is to be understood and appreciated that the various systems may include additional components, modules, etc. and/or may not include all the components, modules, etc. discussed in connection with the figures. A combination of these approaches may also be used. The various aspects disclosed herein can be performed on electrical devices including devices that utilize touch screen display technologies and/or mouse-and-keyboard type interfaces. Examples of such devices include computers (desktop, mobile such as laptop, etc.), smart phones, personal digital assistants (PDAs), Internet platforms, and other electronic devices both wired and wireless.

In addition, the various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

Operational aspects disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

Furthermore, the one or more versions may be implemented as a method, apparatus, or article of manufacture using standard programming and/or engineering techniques to produce software, firmware, hardware, or any combination thereof to control a computer to implement the disclosed aspects. Non-transitory computer readable media can include but are not limited to magnetic storage devices (e.g., hard disk, floppy disk, magnetic strips . . . ), optical disks (e.g., compact disk (CD), digital versatile disk (DVD), BluRay™ . . . ), smart cards, solid-state devices (SSDs), and flash memory devices (e.g., card, stick). Of course, those skilled in the art will recognize many modifications may be made to this configuration without departing from the scope of the disclosed aspects.

The publications discussed herein are provided solely for their disclosure prior to the filing date of the present application. Nothing herein is to be construed as an admission that the present disclosure is not entitled to antedate such publication by virtue of prior disclosure. Further, the dates of publication provided may be different from the actual publication dates which may need to be independently confirmed.

It should be noted that all features, elements, components, functions, and steps described with respect to any embodiment provided herein are intended to be freely combinable and substitutable with those from any other embodiment. If a certain feature, element, component, function, or step is described with respect to only one embodiment, then it should be understood that that feature, element, component, function, or step can be used with every other embodiment described herein unless explicitly stated otherwise. This paragraph therefore serves as antecedent basis and written support for the introduction of claims, at any time, that combine features, elements, components, functions, and steps from different embodiments, or that substitute features, elements, components, functions, and steps from one embodiment with those of another, even if the following description does not explicitly state, in a particular instance, that such combinations or substitutions are possible. It is explicitly acknowledged that express recitation of every possible combination and substitution is overly burdensome, especially given that the permissibility of each and every such combination and substitution will be readily recognized by those of ordinary skill in the art. In many instances, entities are described herein as being coupled to other entities. It should be understood that the terms “coupled” and “connected” (or any of their forms) are used interchangeably herein and, in both cases, are generic to the direct coupling of two entities (without any non-negligible (e.g., parasitic) intervening entities) and the indirect coupling of two entities (with one or more non-negligible intervening entities). Where entities are shown as being directly coupled together, or described as coupled together without description of any intervening entity, it should be understood that those entities can be indirectly coupled together as well unless the context clearly dictates otherwise.

While the embodiments are susceptible to various modifications and alternative forms, specific examples thereof have been shown in the drawings and are herein described in detail. It should be understood, however, that these embodiments are not to be limited to the particular form disclosed, but to the contrary, these embodiments are to cover all modifications, equivalents, and alternatives falling within the spirit of the disclosure. Furthermore, any features, functions, steps, or elements of the embodiments may be recited in or added to the claims, as well as negative limitations that define the inventive scope of the claims by features, functions, steps, or elements that are not within that scope.

What is claimed is:

1. A device for securely locking and charging a smartphone, comprising:
an enclosure having a base portion and a top portion removable from the base portion;
a plurality of illuminating color buttons positioned on a top surface of the top portion;
wherein the device further comprises electronic components configured to:
lock the top portion to the base portion;
generate a first sequence of illuminating colors through the plurality of illuminating color buttons;
receive a second sequence of input selections through the plurality of illuminating color buttons;
upon determining that the second sequence matches the first sequence, unlock the top portion from the base portion.

2. The device of claim 1, wherein the first sequence of illuminating colors is randomly generated.

3. The device of claim 1, wherein the base portion further comprises a docking slot for receiving and charging the smartphone.

4. The device of claim 1, wherein the electronic components are further configured to generate the first sequence of illuminating colors at a level of difficulty progressively more difficult than a level of difficulty of a previous sequence.

5. The device of claim 4, wherein the electronic components are configured to generate the first sequence of illuminating colors faster than the previous sequence.

6. The device of claim 4, wherein the electronic components are configured to generate the first sequence of illuminating colors longer than the previous sequence.

7. The device of claim 1, wherein the electronic components are further configured to sound an alarm when the device is unplugged from a power source.

8. The device of claim 3, wherein, after unlocking the device and sensing that the smartphone has been removed from the docking slot, the electronic components are further configured to activate an alarm counter for a pre-determined amount of time.

9. The device of claim 8, wherein, after the alarm counter expires and sensing that the docking slot has not received a smartphone and the top portion has not been placed on the base portion, the electronic components are further configured to produce an alarm sound.

10. The device of claim 8, wherein, after sensing that the docking slot has received a smartphone and the top portion has been placed on the base portion, the electronic components are further configured to cancel the alarm counter.

11. A method for securely locking and charging a smartphone in a device having an enclosure having a base portion and a top portion removable from the base portion and electronics components for performing the steps of:
locking the top portion to the base portion;
generating a first sequence of illuminating colors through a plurality of illuminating color buttons positioned on a top surface of the top portion;
receiving a second sequence of input selections through the plurality of illuminating color buttons;
upon determining that the second sequence matches the first sequence, unlocking the top portion from the base portion.

12. The method of claim 11, wherein the first sequence of illuminating colors is randomly generated.

13. The method of claim 11, wherein the base portion further comprises a docking slot for receiving and charging the smartphone.

14. The method of claim 11, wherein the electronic components further generate the first sequence of illuminating colors at a level of difficulty progressively more difficult than a level of difficulty of a previous sequence.

15. The method of claim 14, wherein the electronic components generate the first sequence of illuminating colors faster than the previous sequence.

16. The method of claim 14, wherein the electronic components generate the first sequence of illuminating colors longer than the previous sequence.

17. The method of claim 11, wherein the electronic components further sound an alarm when the device is unplugged from a power source.

18. The method of claim 13, wherein, after unlocking the device and sensing that the smartphone has been removed from the docking slot, the electronic components further activate an alarm counter for a pre-determined amount of time.

19. The method of claim 13, wherein, after the alarm counter expires and sensing that the docking slot has not received a smartphone and the top portion has not been placed on the base portion, the electronic components further produce an alarm sound.

20. The method of claim 18, wherein, after sensing that the docking slot has received a smartphone and the top portion has been placed on the base portion, the electronic components further cancel the alarm counter.
